(19) United States
(12) Patent Application Publication
(10) Pub. No.: US 2013/0125981 A1
(43) Pub. Date: May 23, 2013

(54) SOLAR CELL AND MANUFACTURING METHOD THEREOF

(71) Applicant: Dong Keun Lee, Seoul (KR)

(72) Inventor: Dong Keun Lee, Seoul (KR)

(73) Assignee: LG INNOTEK CO., LTD., Seoul (KR)

(21) Appl. No.: 13/813,509

(22) PCT Filed: Oct. 6, 2011
(86) PCT No.: PCT/KR11/07396

§ 371 Date: Jan. 31, 2013

(30) Foreign Application Priority Data
Jan. 24, 2011 (KR) 10-2011-0006988

(51) Int. Cl. H01L 31/0224; H01L 31/18

(52) U.S. Cl. CPC H01L 31/022441; H01L 31/18
USPC 136/256; 438/98

(57) ABSTRACT

Provided is a solar cell including a back electrode layer disposed on a substrate, and having a side surface inclined at a certain angle from the substrate, a light absorbing layer disposed on the back electrode layer, and a window layer disposed on the light absorbing layer.

### TECHNICAL FIELD

Embodiments relate to a solar cell and a method of manufacturing the solar cell.

### BACKGROUND ART

Solar cells, which convert solar energy into electrical energy, are actively commercialized as demand for energy rises.

To manufacture such a solar cell, a back electrode layer, a light absorbing layer, and a window layer are sequentially formed in the form of a thin film on a glass substrate, and a grid electrode is formed thereon. Then, the solar cell is divided into evenly spaced patterns by using a scribing method, and the patterns are connected in series.

When solar cells are manufactured, a patterning process is performed typically at three times. Particularly, while a back electrode layer disposed on a substrate is patterned, side surfaces of the back electrode layer are perpendicular to the substrate.

As such, when the side surfaces of the back electrode layer are perpendicular to the substrate in a line pattern, a gap or inner hole is formed in a coupling portion between the back electrode layer and a light absorbing layer formed on the back electrode layer. The gap or inner hole may degrade surface uniformity of the coupling portion between the back electrode layer and the light absorbing layer, thus jeopardizing reliability of the solar cell.

### DISCLOSURE OF INVENTION

### Technical Problem

Embodiments provide a solar cell and a method of manufacturing the solar cell, which prevent a gap or inner hole from being formed in a coupling portion between a back electrode layer and a light absorbing layer, thereby improving durability and reliability of the solar cell.

### Solution to Problem

In one embodiment, a solar cell includes: a back electrode layer disposed on a substrate, and having a side surface inclined at a certain angle from the substrate; a light absorbing layer disposed on the back electrode layer; and a window layer disposed on the light absorbing layer.

In another embodiment, a solar cell includes: a back electrode layer disposed on a substrate, and having a side surface forming a first inclination angle with the substrate; a light absorbing layer disposed on the back electrode layer, and forming a second inclination angle with the substrate; and a window layer disposed on the light absorbing layer.

In another embodiment, a method of manufacturing a solar cell includes: forming a back electrode on a substrate; patterning the back electrode to form a back electrode layer having a side surface inclined at a certain angle from the substrate; forming a light absorbing layer on the back electrode layer; and forming a window layer on the light absorbing layer.

The details of one or more embodiments are set forth in the accompanying drawings and the description below. Other features will be apparent from the description and drawings, and from the claims.

### Advantageous Effects of Invention

According to embodiments, a back electrode layer of a solar cell has inclined side surfaces to decrease the height of a gap in a coupling portion between the back electrode layer and a light absorbing layer disposed on the back electrode layer. Accordingly, the number of gaps or inner holes in the coupling portion between the back electrode layer and the light absorbing layer is decreased, thus improving surface uniformity of the coupling portion.

Therefore, durability and reliability of the solar cell are more improved.

### BRIEF DESCRIPTION OF DRAWINGS

FIG. 1 is a cross-sectional view illustrating a solar cell according to an embodiment.

FIG. 2 is a cross-sectional view illustrating a back electrode layer and a light absorbing layer of a solar cell in the related art.

FIG. 3 is a cross-sectional view illustrating a back electrode layer of a solar cell according to an embodiment.

FIGS. 4 and 5 are cross-sectional views illustrating the length of a slope of a back electrode layer according to an embodiment.

FIG. 6 is a cross-sectional view illustrating a light absorbing layer formed on a back electrode layer according to an embodiment.

FIGS. 7 to 9 are cross-sectional views illustrating a back electrode layer according to an embodiment.

FIG. 10 is a cross-sectional view illustrating a solar cell according to an embodiment.

FIGS. 11 to 17 are cross-sectional views illustrating a method of manufacturing a solar cell according to an embodiment.

### MODE FOR THE INVENTION

In the description of embodiments, it will be understood that when a panel, line, cell, device, surface, or pattern is referred to as being ‘on’ or ‘under’ another panel, line, cell, device, surface, or pattern, the terminology of ‘on’ and ‘under’ includes both the meanings of ‘directly’ and ‘indirectly’. Further, the reference about ‘on’ and ‘under’ each component will be made on the basis of drawings. In addition, the sizes of elements and the relative sizes between elements may be exaggerated for further understanding of the present disclosure.

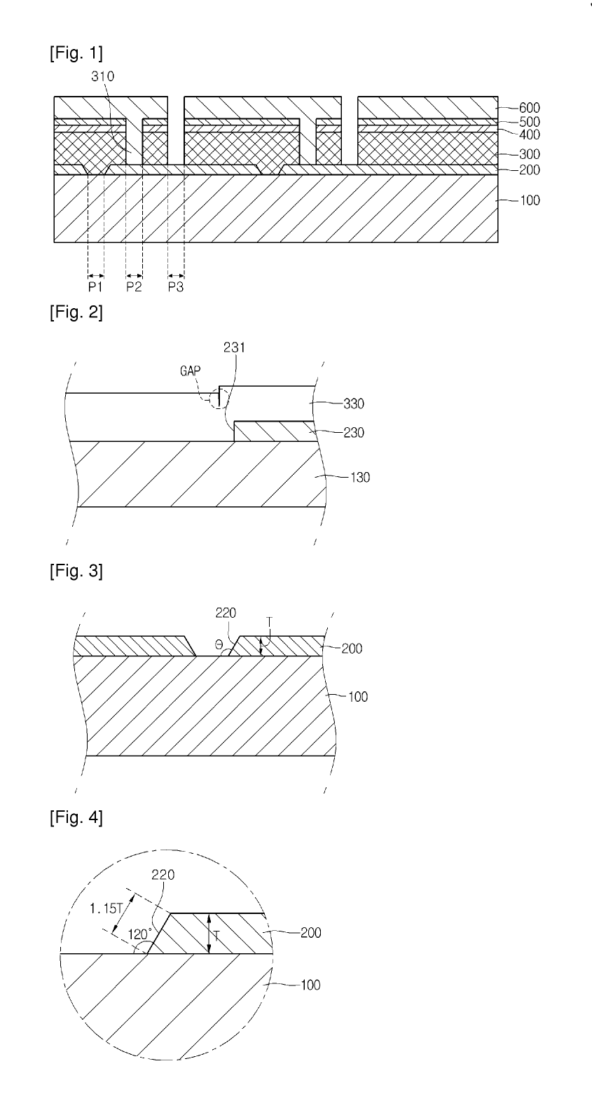

FIG. 1 is a cross-sectional view illustrating a solar cell according to an embodiment. Referring to FIG. 1, a solar cell according to the current embodiment includes: a substrate 100; a back electrode layer 200 disposed on the substrate 100, and having side surfaces inclined at a certain angle from the substrate 100; a light absorbing layer 300 disposed on the back electrode layer 200; a buffer layer 400; a high resistant buffer layer 500; and a window layer 600. The buffer layer 400, the high resistant buffer layer 500, and the window layer 600 are sequentially formed on the light absorbing layer 300.

The substrate 100 has a plate shape, and supports the back electrode layer 200, the light absorbing layer 300, the buffer layer 400, the high resistant buffer layer 500, and the window layer 600.

The substrate 100 may be transparent, and rigid or flexible.

The substrate 100 may be an electrical insulator. For example, the substrate 100 may be a glass substrate, a plastic substrate, or a metal substrate. In more detail, the substrate 100 may be formed of soda lime glass including sodium. Alternatively, the substrate 100 may be formed of ceramic such as alumina, stainless steel, or flexible polymer.

The back electrode layer 200 is disposed on the substrate 100. The back electrode layer 200 is a conductive layer. The back electrode layer 200 may be formed of one of molybdenum (Mo), gold (Au), aluminum (Al), chrome (Cr), tungsten (W), and copper (Cu), but is not limited thereto. Especially, since molybdenum is less different in coefficient of thermal expansion from the substrate 100 than the other elements, molybdenum has excellent adherence thereto and is resistant to exfoliation, and substantially satisfies characteristics required by the back electrode layer 200.

The back electrode layer 200 may include two or more layers. In this case, the two or more layers may be formed of the same metal or different metals.

The back electrode layer 200 is divided into back electrode layers by first through recesses P1. The first through recesses P1 may have not only a stripe shape as illustrated in FIG. 1, but also a matrix shape, but is not limited thereto. The first through recesses P1 may have a width ranging from about 80 μm to about 200 μm, but is not limited thereto.

FIG. 2 is a cross-sectional view illustrating a back electrode layer 230 and a light absorbing layer 330 of a solar cell in the related art. Referring to FIG. 2, a side surface 231 of the back electrode layer 230 is perpendicular to a substrate 130. That is, a stepped portion 231 is disposed between the back electrode layer 230 and the substrate 130. Then, the light absorbing layer 330 is formed on the back electrode layer 230. At this point, the stepped portion 231 causes a gap or a defect such as an inner hole in a coupling portion between the light absorbing layer 330 and the back electrode layer 230. The gap or defect degrades surface uniformity of the coupling portion between the back electrode layer 230 and the light absorbing layer 330, thus jeopardizing durability and reliability of the solar cell.

To address these limitations, according to the present disclosure, side surfaces of a back electrode layer are inclined to decrease the height of a gap in the coupling portion between the back electrode layer and a light absorbing layer, and improve surface uniformity of a solar cell.

Referring to FIG. 3, side surfaces 220 of the back electrode layer 200 are inclined. That is, the side surfaces 220 are inclined at an angle θ from the substrate 100.

The side surfaces 220 of the back electrode layer 200 may be inclined toward an upper outer side of the substrate 100. The angle θ may range from 120° to about 150°. Particularly, the angle θ may range from 130° to about 150°.

The length of the side surfaces 220 may depend on the angle θ between the side surfaces 220 and the substrate 100. For example, the length of the side surfaces 220 may range from about 1 μm to about 3 μm, but is not limited thereto.

The length of the side surfaces 220 may be about 1.15 times to about 2 times greater than a thickness T of the back electrode layer 200, but is not limited thereto.

Referring to FIG. 4, when the angle θ is about 120°, the length of the side surfaces 220 may be about 1.15 times greater than the thickness T. In this case, the thickness T may range from about 0.2 μm to about 1.2 μm, but is not limited thereto.

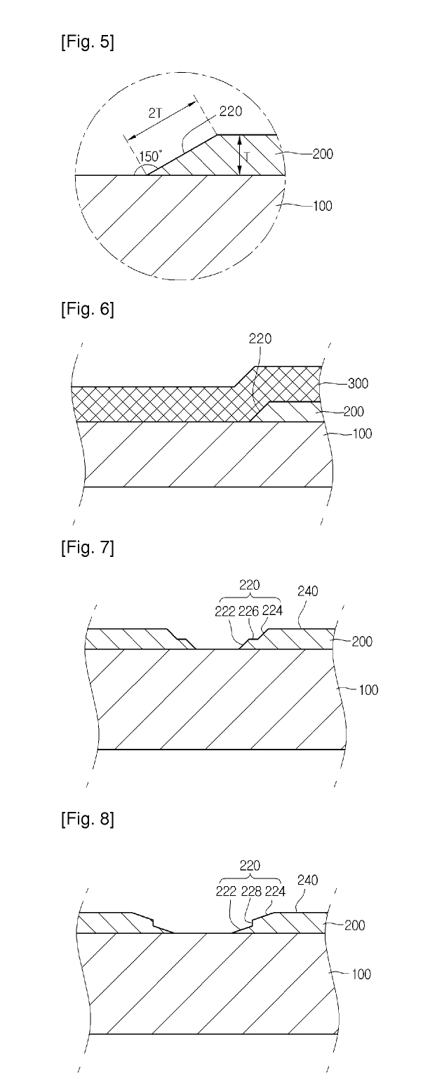

Referring to FIG. 5, when the angle θ is about 150°, the length of the side surface 220 may be about 2 times greater than the thickness T. In this case, the thickness T may range from about 0.2 μm to about 1.2 μm, but is not limited thereto.

Referring to FIG. 6, the light absorbing layer 300 conforms with the back electrode layer 200 having the side surfaces 220. That is, according to the current embodiment, the height of a gap in the coupling portion between the back electrode layer 200 and the light absorbing layer 300. Accordingly, surface uniformity of the coupling portion between the back electrode layer 200 and the light absorbing layer 300 can be enhanced, thus improving durability and reliability of the solar cell.

Although the side surfaces 220 of the back electrode layer 200 are provided with a single slope as described above, the present disclosure is not limited thereto, and thus, the side surfaces 220 may be provided with a plurality of slopes as illustrated in FIGS. 7 to 9. In this case, the side surfaces 220 of the back electrode layer 200 have bent portions for connecting the slopes to each other. The bent portions may include a horizontal surface 226 or a vertical surface 228.

Referring to FIG. 7, the side surfaces 220 may include a first slope 222 and a second slope 224, which are inclined at a certain angle from the substrate 100, and the horizontal surface 226 may be disposed between the first slope 222 and the second slope 224 to connect them to each other.

The first slope 222 extends to the edge of the substrate 100 from the top surface of the substrate 100, and the second slope 224 connects to a top surface 240 of the back electrode layer 200. The horizontal surface 226 is parallel to the substrate 100, and connects an end of the first slope 222 to an end of the second slope 224.

Each of the first and second slopes 222 and 224 extending toward the outside edge of the substrate 100 may be inclined at a certain angle. For example, each of the first and second slopes 222 and 224 may be inclined at an angle ranging from about 120° to about 150° from the substrate 100, but is not limited thereto.

Furthermore, the first and second slopes 222 and 224 may be inclined at the same angle or different angles from the substrate 100. The first and second slopes 222 and 224 may have the same length or different lengths. The length of the horizontal surface 226 may be shorter than the length of the first slope 222 and the second slope 224.

Referring to FIG. 8, the side surfaces 220 may include: a first slope 222 and a second slope 224, which are inclined at a certain angle from the substrate 100; and the vertical surface 228 disposed between the first slope 222 and the second slope 224 to connect them to each other. To this end, the vertical surface 228 may connect an upper end of the first slope 222 to a lower end the second slope 224, and be perpendicular to the substrate 100. The length of the vertical surface 228 may be shorter than the length of the first slope 222 and the second slope 224.

Although the horizontal surface 226 and the vertical surface 228 connect the first slope 222 to the second slope 224 as described above, embodiments are not limited thereto, and thus, bent portions may be provided at various angles.

As described above, when the side surface 220 is provided with a plurality of slopes, the side surfaces 220 can be more gently inclined from the substrate 100. Accordingly, the height of a gap in the coupling portion between the back electrode layer 200 and the light absorbing layer 300 can be decreased, and surface uniformity of the coupling portion between the back electrode layer 200 and the light absorbing layer 300 can be improved.

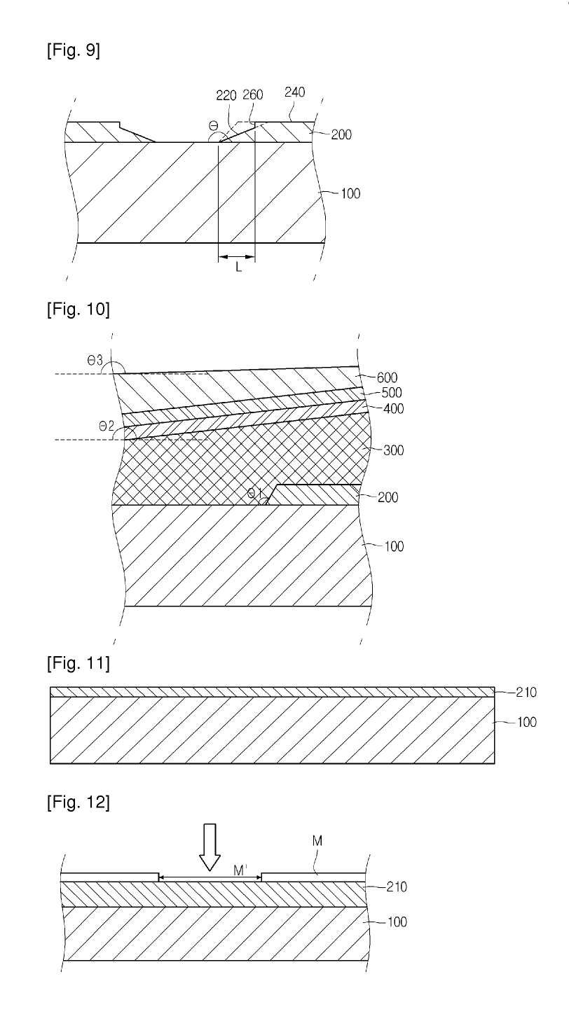

Alternatively, referring to FIG. 9, the side surfaces 220 of the back electrode layer 200 may have a length L from an exposed portion of the substrate 100. For example, the length L may range from about 1 μm to about 3 μm.

If the side surface 220 covers a too wide area, the top surface 240 of the back electrode layer 200 is shorten, so that a mean thickness of the back electrode layer 200 may be too small to function as an electrode. On the contrary, if the side surface 220 covers a too narrow area, a portion including the side surface 220 may be too small to uniformly form the light absorbing layer 300 on the back electrode layer 200.

Thus, the side surface 220 may include a vertical portion 260 in the upper portion of the back electrode layer 200 to connect a slope to the top surface 240 of the back electrode layer 200. In this case, the slope of the side surface 220 may be provided in plurality.

As described above, the side surfaces 220 have an inclined planar shape, but are not limited thereto. That is, the side surfaces 220 may have a curved shape.

The light absorbing layer 300 is disposed on the back electrode layer 200. The light absorbing layer 300 include a Group I-III-VI compound. For example, the light absorbing layer 300 may have a copper-indium-gallium-selenide based (Cu(In, Ga)(Se, S)₂; CIGSS based) crystal structure, a copper-indium-selenide based crystal structure, or a copper-gallium-selenide based crystal structure.

The buffer layer 400 is disposed on the light absorbing layer 300. The buffer layer 400 may function as a buffer against an energy gap difference between the light absorbing layer 300 and the window layer 600 to be described later.

The buffer layer 400 includes cadmium sulfide, ZnS, InₓS_{y}, and InₓSe_{y}Zn(O, OH). The buffer layer 400 may have a thickness ranging from about 50 nm to about 150 nm, and an energy band gap ranging from about 2.2 eV to about 2.4 eV.

The high resistant buffer layer 500 is disposed on the buffer layer 400. The high resistant buffer layer 500 has high resistance to be insulated from the window layer 600 and be resistant to a shock.

The high resistance buffer layer 500 may be formed of an intrinsic zinc oxide (i-ZnO). The high resistant buffer layer 500 may have an energy band gap ranging from about 3.1 eV to about 3.3 eV. The high resistant buffer layer 500 may be removed.

The light absorbing layer 300, the buffer layer 400, and the high resistant buffer layer 500 include second through recesses P2. That is, the second through recesses P2 may pass through the light absorbing layer 300, the buffer layer 400, and the high resistant buffer layer 500. The back electrode layer 200 is partially exposed through the second through recesses P2. The second through recesses P1 may have a width ranging from about 80 μm to about 200 μm, but are not limited thereto.

The second through recesses P1 may be filled with a material used to form the window layer 600, to thereby form connecting lines 310. The connecting lines 310 may electrically connect the window layer 600 to the back electrode layer 200.

The window layer 600 is a light-transmitting and electrically conductive material. The window layer 600 may have characteristics of an n type semiconductor. In this case, the window layer 600 forms an n type semiconductor layer with the buffer layer 400 to form a pn junction with the light absorbing layer 300 that is a p type semiconductor layer. For example, the window layer 600 may be formed of aluminum-doped zinc oxide (AZO). The window layer 600 may have a thickness ranging from about 100 nm to about 500 nm

The light absorbing layer 300, the buffer layer 400, and the high resistant buffer layer 500, the window layer 600 include third through recesses P3. That is, the third through recesses P3 may pass through the light absorbing layer 300, the buffer layer 400, and the high resistant buffer layer 500, the window layer 600. The back electrode layer 200 is partially exposed through the third through recesses P3. The third through recesses P3 may have a width ranging from about 80 μm to about 200 μm, but are not limited thereto.

Referring to FIG. 10, in a solar cell according to another embodiment, a light absorbing layer 300 deposited on a back electrode layer 200 may form an inclination angle with the substrate 100 by means of the back electrode layer 200 having a side surface 220 that is inclined. That is, the solar cell according to the current embodiment includes; the back electrode layer 200 disposed on the substrate 100, and having the side surface 220 forming a first inclination angle θ₁ with the substrate 100; the light absorbing layer 300 disposed on the back electrode layer 200, and forming a second inclination angle θ₂ with the substrate 100; and a window layer 600 disposed on the light absorbing layer 300.

The window layer 600 forms a third inclination angle θ₃ with the substrate 100. That is, both the light absorbing layer 300 and the window layer 600 may be inclined from the substrate 100 by means of the back electrode layer 200 having the side surface 220 inclined at the first inclination angle θ₁.

The second inclination angle θ₂ is greater than the first inclination angle θ₁. The third inclination angle θ₃ is greater than the second inclination angle θ₂. That is, as a height increases from the substrate 100, an inclination angle may increase from the substrate 100, but the present disclosure is not limited thereto. For example, the first inclination angle θ₁ may range from about 120° to about 150°, but is not limited thereto.

Hereinafter, a method of manufacturing a solar cell according to an embodiment will now be described with reference to the accompanying drawings. FIGS. 11 to 17 are cross-sectional views illustrating a method of manufacturing a solar cell according to an embodiment. A description of the method refers to the above description of the solar cell. The above description of the solar cell is substantially coupled to the description of the method.

Referring to FIGS. 11 to 14, a back electrode 210 is formed on the substrate 100, and is patterned to form the side surfaces 220 inclined at a certain angle from the substrate 100.

The back electrode 210 may be formed through physical vapor deposition (PVD) or plating. A diffusion barrier may be disposed between the substrate 100 and the back electrode layer 200.

The back electrode 210 may be patterned using any typical method employing inclination etching. For example, the back electrode 210 may be patterned using various methods such as a wet etch process using a mask, a dry etch process using plasma, or a laser process. When the laser process is used, the back electrode 210 may be sequentially melted, changing the shape of a laser beam, so that the side surfaces 220 can be easily inclined.

FIGS. 12 to 14 are cross-sectional views illustrating a method of patterning the back electrode 210 through the wet etch process using a mask. Referring to FIG. 12, a mask pattern M including an opening M′ is formed on the back electrode 210, and the back electrode 210 is etched using a wet etch solution. The wet etch solution may be a Mo-etchant.

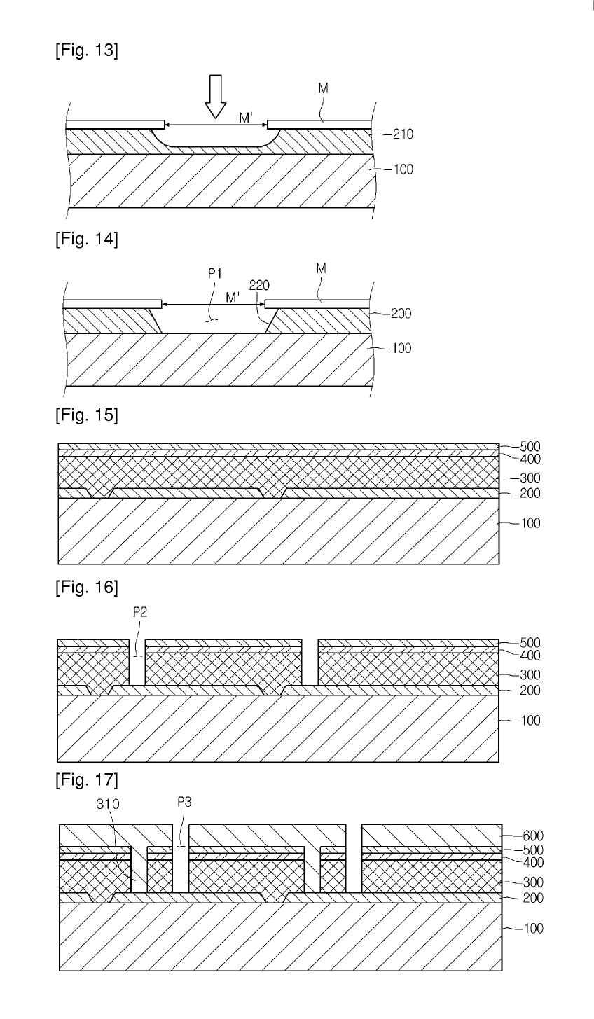

After a certain time, as illustrated in FIG. 13, a recessed pattern is formed in a portion of the back electrode 210 exposed through the opening M′ of the mask pattern M. At this point, the portion of the back electrode 210 exposed through the opening M′ may be etched not only in a perpendicular direction to the substrate 100 but also in a parallel direction to the substrate 10.

Referring to FIG. 14, the wet etch process is performed for a certain time, to thereby complete a first patterning process of forming the first through recess P1. That is, the first patterning process is performed to partially expose the substrate 100, and incline the side surfaces 220 from the substrate 100.

The wet etch process or the dry etch process may be performed at several times to provide the back electrode layer 200 with a plurality of slopes as illustrated in FIGS. 7 to 9.

Next, referring to FIG. 15, the light absorbing layer 300, the buffer layer 400, and the high resistant buffer layer 500 are sequentially formed on the back electrode layer 200.

The light absorbing layer 300 may be formed of a Group I-III-VI compound. In more detail, the light absorbing layer 300 includes may have a copper-indium-gallium-selenide based (Cu(In, Ga)Se₂; CIGS based) compound. Alternatively, the light absorbing layer 300 may include a copper-indium-selenide based (CuInSe₂; CIS based) compound, or a copper-gallium-selenide based (CuGaSe₂; CGS based) compound.

For example, a CIG based metal precursor film may be formed on the back electrode layer 200 with a copper target, an indium target, and a gallium target to form the light absorbing layer 300 on the back electrode layer 200. Thereafter, the CIG based metal precursor film reacts with selenium (Se) through a selenization process to form a CIGS based light absorbing layer as the light absorbing layer 300.

Alternatively, the light absorbing layer 300 may be formed from copper (Cu) indium (In) gallium (Ga), and selenide (Se) through co-evaporation.

The buffer layer 400 may be formed by depositing cadmium sulfide on the light absorbing layer 300 through chemical bath deposition (CBD).

The high resistance buffer layer 500 is formed on the buffer layer 400. The high resistance buffer layer 500 includes an intrinsic zinc oxide (i-ZnO). The high resistant buffer layer 500 may have an energy band gap ranging from about 3.1 eV to about 3.3 eV. The high resistant buffer layer 500 may be removed.

Subsequently, referring to FIG. 16, a second patterning process is performed to form the second through recesses P2 in the light absorbing layer 300, the buffer layer 400, and the high resistant buffer layer 500. The second through recesses P2 are spaced a certain distance from the first through recesses P1. The second through recesses P2 may be formed using a mechanical method or a laser irradiation method. For example, the second through recesses P2 may be formed through a scribing process. The second through recesses P2 are formed not to correspond to an ohmic layer 800.

Referring to FIG. 17, the window layer 600 is formed on the high resistant buffer layer 500. The window layer 600 may be formed by depositing an electrically conductive transparent material on the high resistance buffer layer 500. At this point, the second through recesses P2 may be filled with the transparent material to form the connecting lines 310. The connecting lines 310 may electrically connect the window layer 600 to the back electrode layer 200.

Thereafter, a third patterning process is performed to form the third through recesses P3 passing through the light absorbing layer 300, the buffer layer 400, and the high resistant buffer layer 500, the window layer 600. The third through recesses P3 are spaced a certain distance from the second through recesses P2.

The third through recesses P3 define solar cells islands C1, C2, and C3 including the back electrode layer 200, the light absorbing layer 300, the buffer layer 400, and the high resistant buffer layer 500. That is, the solar cell islands C1, C2, and C3 are isolated by the third through recesses P3. The third through recesses P3 may be formed using a mechanical method or a laser irradiation method, to thereby expose the top surface of the back electrode layer 200.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell comprising:
a back electrode layer disposed on a substrate, and having a side surface inclined at a certain angle from the substrate;
a light absorbing layer disposed on the back electrode layer; and
a window layer disposed on the light absorbing layer.

2. The solar cell according to claim 1, wherein the certain angle ranges from about 120° to about 150°.

3. The solar cell according to claim 1, wherein the side surface of the back electrode layer comprises a planar surface or a curved surface.

4. The solar cell according to claim 1, wherein the side surface of the back electrode layer has a length ranging from about 1 μm to about 3 μm.

5. The solar cell according to claim 1, wherein the side surface of the back electrode layer comprises slopes.

6. The solar cell according to claim 5, wherein the side surface of the back electrode layer comprises a bent portion.

7. The solar cell according to claim 5, wherein angles formed by the slopes and the substrate are different from each other.

8. The solar cell according to claim 5, wherein the slope comprises a surface perpendicular to the substrate.

9. The solar cell according to claim 1, wherein the side surface of the back electrode layer is inclined toward an upper outer side of the substrate.

10. A solar cell comprising:
a back electrode layer disposed on a substrate, and having a side surface forming a first inclination angle with the substrate;
a light absorbing layer disposed on the back electrode layer, and
forming a second inclination angle with the substrate; and
a window layer disposed on the light absorbing layer.

11. The solar cell according to claim 10, wherein the first inclination angle ranges from about 120° to about 150°.

12. The solar cell according to claim 10, wherein the window layer forms a third inclination angle with the substrate.

13. The solar cell according to claim 12, wherein the first inclination angle is smaller than the second inclination angle, and the second inclination angle is smaller than the third inclination angle.

14. A method of manufacturing a solar cell, comprising:
forming a back electrode on a substrate;
patterning the back electrode to form a back electrode layer having a side surface inclined at a certain angle from the substrate;
forming a light absorbing layer on the back electrode layer; and
forming a window layer on the light absorbing layer.

15. The method according to claim 14, wherein the certain angle ranges from about 120° to about 150°.

16. The method according to claim 14, wherein the forming of the back electrode layer comprises:
forming a mask including an opening, on the back electrode; and
etching a portion of the back electrode exposed through the opening, through inclination etching with an etch solution.

17. The method according to claim 14, wherein the back electrode is patterned to expose a portion of the substrate.

18. The method according to claim 17, wherein the side surface of the back electrode layer extends through a certain distance from the exposed portion of the substrate.

19. The method according to claim 18, wherein the certain distance ranges from about 1 μm to about 3 μm.
